(19) United States
(12) Patent Application Publication
(10) Pub. No.: US 2026/0018458 A1
(43) Pub. Date: Jan. 15, 2026

(54) SEMICONDUCTOR DEVICES AND METHODS OF MANUFACTURING THE SAME

(71) Applicants: Samsung Electronics Co., Ltd., Suwon-si (KR); Merck Patent GmbH, Darmstadt (DE)

(72) Inventors: Younghun Sung, Suwon-si (KR); Guo Liu, Philadelphia, PA (US); Bhushan Zope, Philadelphia, PA (US); Soyoung Lee, Suwon-si (KR); Hyunho Kim, Suwon-si (KR); Youn Joung Cho, Suwon-si (KR); Byungkeun Hwang, Suwon-si (KR); Sunhye Hwang, Suwon-si (KR)

(73) Assignee: EMD Performance Materials Corp., Philadelphia, PA (US)

(21) Appl. No.: 18/769,944

(22) Filed: Jul. 11, 2024

(51) Int. Cl. H01L 21/768; H01L 23/522

(52) U.S. Cl. CPC H01L 21/76805; H01L 21/76834; H01L 21/76877; H01L 23/5226

(57) ABSTRACT

A method of manufacturing a semiconductor device comprising: forming a first layer in which first conductive patterns and first dielectric patterns are alternately arranged; forming passivation layers on the first conductive patterns, respectively; and forming second dielectric patterns on the first dielectric patterns, respectively, by an area-selective atomic layer deposition at a first temperature, wherein the first temperature is 350° C. or less, wherein the area-selective atomic layer deposition includes: pulsing a metal catalyst; performing a primary purge by a purge gas; sub-pulsing a reaction precursor at least once; and performing a secondary purge by the purge gas after each of the sub-pulsing.

### BACKGROUND OF THE INVENTION

### 1. Field of the Invention

The present disclosure relates to semiconductor devices and methods of manufacturing the same.

### 2. Description of the Related Art

A semiconductor device may include a plurality of vertically stacked metal structures and vias to electrically connect the metal structures.

Meanwhile, as a semiconductor device is highly integrated, more devices are needed to be formed per unit area, and thus a gap between adjacent conductive patterns in a horizontal direction may become narrow. As a result, a via connected to a conductive pattern may unintentionally come into contact to adjacent conductive pattern, and thus a short circuit may occur.

### SUMMARY OF THE INVENTION

Some embodiments of the inventive concept provide methods of manufacturing semiconductor devices capable of reducing or preventing electrical contact between a via, which is connected to a conductive pattern, and an adjacent conductive pattern, which is adjacent to the conductive pattern.

Some embodiments of the inventive concept provide semiconductor devices manufactured by the methods.

A method of manufacturing a semiconductor device may comprise: forming a first layer in which first conductive patterns and first dielectric patterns are alternately arranged; forming passivation layers on the first conductive patterns, respectively; and forming second dielectric patterns on the first dielectric patterns, respectively, by an area-selective atomic layer deposition at a first temperature, wherein the first temperature may be 350° C. or less, wherein the area-selective atomic layer deposition may include: pulsing a metal catalyst; performing a primary purge by a purge gas; sub-pulsing a reaction precursor at least once; and performing a secondary purge by the purge gas after each of the sub-pulsing.

The purge gas may be continuously supplied with a constant flow rate and a constant pressure during the area-selective atomic layer deposition.

The constant pressure of the purge gas may be 1 Torr or less.

The area-selective atomic layer deposition may further include pumping the purge gas between the sub-pulsing the reaction precursor and the secondary purge.

The purge gas of the performing the primary purge may have a first flow rate and a first pressure, the purge gas of the pumping the purge gas may have a second flow rate and a second pressure, and the purge gas of the performing the second purge may have a third flow rate and a third pressure.

The first flow rate may be greater than the second flow rate, the third flow rate may be greater than the second flow rate, the first pressure may be greater than the second pressure, and the third pressure may be greater than the second pressure.

The second flow rate may be zero (0) standard cubic centimeters per minute (sccm), and the second pressure may be 0.1 Torr or less.

The first temperature may be 150° C. to 350° C.

The metal catalyst may include trimethylaluminum, triethylaluminum, dimethylaluminum iso-propoxide, and/or a combination thereof.

The reaction precursor may be a silanol precursor, and the second dielectric patterns may include silicon oxide.

The silanol precursor may include tris(t-pentoxy)silanol, bis(t-pentoxy)(t-butoxy)silanol, and/or a combination thereof.

The forming the passivation layers may include supplying a self-assembled molecule that includes a thiol group material, an amine group material, and/or a carboxylic group material.

The supplying the self-assembled molecule may be performed at a second temperature of 100° C. to 350° C.

The forming the passivation layers may further include performing additional purge after the supplying the self-assembled molecule.

The method may further include repeating the area-selective atomic layer deposition until the second dielectric patterns reach to a desired thickness, and performing a tertiary purge before the repeating the area-selective atomic layer deposition.

The second dielectric patterns may include a dielectric material that has a dielectric constant of 2.5 to 6.0.

The second dielectric patterns may include a dielectric material that has a leakage current of 3×10⁻⁷ A/cm² or less at 5 MV/cm.

The first dielectric patterns and the second dielectric patterns each may include silicon oxide.

The method may further include forming vias electrically connected to the first conductive patterns, and forming second conductive patterns electrically connected to the first conductive patterns through the vias.

According to some embodiments, a semiconductor device may include a first layer including first conductive patterns and first dielectric patterns; second dielectric patterns on the first dielectric patterns, wherein the second dielectric patterns may have same planar shapes as the first dielectric patterns, respectively, and may include a dielectric material that has a dielectric constant of 2.5 to 6.0 and a leakage current of 3×10⁻⁷ A/cm² or less at 5 MV/cm; a second layer electrically connected to the first conductive patterns, wherein the second layer may include vias that are in contact with the second dielectric patterns; and a third layer including second conductive patterns that are electrically connected to the first conductive patterns through the vias, wherein the semiconductor device may be manufactured by a method comprising: forming the first layer in which the first conductive patterns and the first dielectric patterns are alternately arranged; forming passivation layers on the first conductive patterns, respectively; and forming the second dielectric patterns on the first dielectric patterns, respectively, by an area-selective atomic layer deposition at a first temperature, wherein the first temperature may be 350° C. or less, and wherein the area-selective atomic layer deposition may include: pulsing a metal catalyst; performing a primary purge by a purge gas; sub-pulsing a reaction precursor at least once; and performing a secondary purge by the purge gas after each of the sub-pulsing.

By selectively forming dielectric patterns with good film quality at a relatively low temperature, (unintended) electrical contact between a via connected to one conductive pattern and adjacent conductive pattern may be reduced or prevented without deterioration of electrical characteristics.

### BRIEF DESCRIPTION OF THE DRAWINGS

FIG. 1 is a schematic diagram of a semiconductor device according to some embodiments,

FIG. 2 is a cross-sectional view showing some embodiments of a metal connection portion of the semiconductor device of FIG. 1,

FIGS. 3 to 8 are cross-sectional views showing some embodiments of a method of manufacturing the metal connection portion of FIG. 2,

FIG. 9 is a schematic diagram showing pressure and flow rate of purge gas in a continuous flow process,

FIG. 10 is a schematic diagram showing pressure and flow rate of purge gas in the pump-purge process,

FIG. 11 is a Fourier Transform Infrared Spectroscopy (FTIR) analysis graph of the silicon oxide films obtained in Examples,

FIG. 12 is a graph showing the changes in leakage current at 5 MV/cm according to deposition temperature and purge gas pressure during the formation of silicon oxide films, and

FIG. 13 is a graph showing the changes in breakdown field according to deposition temperature and purge gas pressure during the formation of silicon oxide films.

### DETAILED DESCRIPTION

The present disclosure will be described more fully hereinafter with reference to the accompanying drawings, in which embodiments of the disclosure are shown.

As those skilled in the art would realize, the described embodiments may be modified in various ways, all without departing from the scope of the present disclosure. Accordingly, the drawings and description are to be regarded as illustrative in nature and not restrictive. Uke reference numerals designate like elements throughout the specification unless clearly indicated otherwise.

In the flowchart described with reference to the drawings, an order of operations may be changed, various operations may be merged, a certain operation may be divided, and a certain operation may not be performed (e.g., may be omitted).

In addition, a singular form may be intended to include a plural form as well, unless the explicit expression such as “one” or “single” is used. Terms including ordinal numbers such as first, second, and the like will be used only to describe various constituent elements, and are not to be interpreted as limiting these constituent elements. These terms may be used for a purpose of distinguishing one constituent element from other constituent elements. Hereinafter, a semiconductor device according to some embodiments is described.

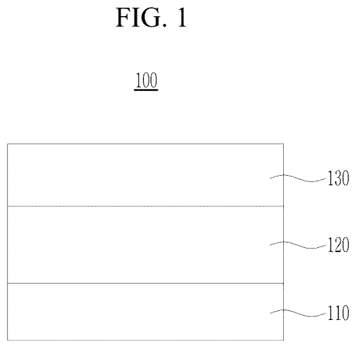

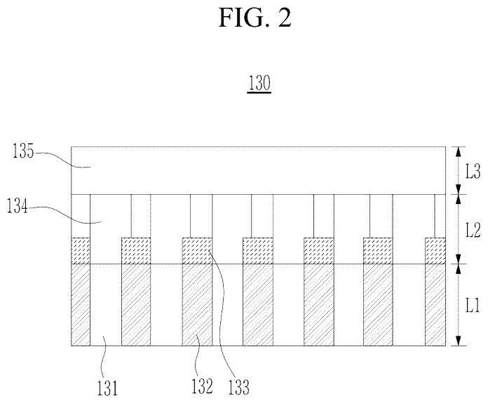

FIG. 1 is a schematic diagram of a semiconductor device 100 according to some embodiments, and FIG. 2 is a cross-sectional view showing some embodiments of a metal connection portion 130 of the semiconductor device 100 of FIG. 1.

The semiconductor device 100, according to some embodiments, may be an integrated circuit device, including, for example, a memory semiconductor and/or a logic semiconductor. The semiconductor device 100 may include a substrate 110, such as a silicon wafer, a logic circuit portion 120 (on the substrate 110), and the metal connection portion 130 (on the logic circuit portion 120). As used herein, the term “and/or” includes any and all combinations of one or more of the associated listed items.

The logic circuit portion 120 may include logic circuit elements such as a transistor, a capacitor, and/or a resistor, and may be formed by a front end of line (FEOL) process and/or middle end of line (MEOL) process.

The metal connection portion 130 may include conductive patterns (e.g., first conductive patterns 131 and/or second conductive patterns 135) (electrically) connected to a logic circuit element of the logic circuit portion 120, a dielectric (e.g., first dielectric patterns 132 and/or second dielectric patterns 133) that (electrically) separates the conductive patterns in a vertical and/or a horizontal direction (e.g., a first horizontal direction and/or a second horizontal direction), and vias (e.g., vias 134) for (electrically) connecting the conductive patterns in the vertical direction. The metal connection portion 130 may be formed by back end of line (BEOL) process. The first horizontal direction and a second horizontal direction may be parallel with an upper surface and/or a lower surface of the substrate 110, and the vertical direction may be perpendicular to the upper surface and/or the lower surface of the substrate 110. The first horizontal direction and the second horizontal direction may intersect each other. For example, the first horizontal direction and the second horizontal direction may be perpendicular to each other. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

Referring to FIG. 2, the metal connection portion 130 may include a first layer L1, a second layer L2, and a third layer L3 stacked in the vertical direction. In the drawing, for convenience of explanation, a structure including the first layer L1, the second layer L2, and the third layer L3 is illustrated, but the metal connection portion 130 may include more layers stacked in two or three dimensions.

The first layer L1 may include first conductive patterns 131 and first dielectric patterns 132 arranged alternately (in the first horizontal direction). The first layer L1 may be an interlayer dielectric layer, and the first conductive patterns 131 may be (embedded) in the interlayer dielectric layer. The first conductive patterns 131 may be formed by a damascene process, but is not limited thereto.

The first conductive patterns 131 may include metal or metal alloy, for example, copper (e.g., Cu), titanium (e.g., Ti), tantalum (e.g., Ta), aluminum (e.g., Al), tungsten (e.g., W), cobalt (e.g., Co), molybdenum (e.g., Mo), ruthenium (e.g., Ru), an alloy thereof, and/or combinations thereof, but is not limited thereto. The width of at least one of the first conductive patterns 131 (in the first horizontal direction) may be, for example, (about) 30 nm or less. For example, the width of at least one of the first conductive patterns 131 in the first horizontal direction may be (about) 1 nm to 30 nm, (about) 1 nm to 25 nm, (about) 1 nm to 20 nm, (about) 1 nm to 15 nm, (about) 1 nm to 10 nm, (about) 1 nm to 7 nm, or (about) 1 nm to 5 nm.

The first dielectric patterns 132 may be the remaining portions excluding the first conductive patterns 131 of the interlayer dielectric layer of the first layer L1. For example, one of the first dielectric patterns 132 may be positioned between adjacent first conductive patterns 131 among the first conductive patterns 131 to (electrically) separate the adjacent first conductive patterns 131 from each other. The first dielectric patterns 132 may include, for example, a dielectric material having a dielectric constant of (about) 2.5 to (about) 6.0. For example, the first dielectric patterns 132 may include a dielectric material having a dielectric constant of (about) 2.5 to (about) 5.0, (about) 2.7 to (about) 5.0, or (about) 3.0 to (about) 5.0. The first dielectric patterns 132 may include, for example, a silicon oxide.

The second dielectric patterns 133 may be selectively formed on the first dielectric patterns 132. The planar shape of each of the second dielectric patterns 133 may be (substantially) the same as the planar shape of each of the first dielectric patterns 132, and each of them may be linear extending in one direction. For example, the first dielectric patterns 132 and the second dielectric patterns 133 may be aligned in the vertical direction, respectively. For example, the first dielectric patterns 132 and the second dielectric patterns 133 may extend in the second horizontal direction. Each of the second dielectric patterns 133 may be selectively formed on each of the first dielectric patterns 132 by, for example, an area-selective atomic layer deposition process, as described later, without a patterning process. The second dielectric patterns 133 may be positioned on the first dielectric patterns 132, and thus one of the vias 134 of the second layer L2, which will be described later, may be prevented from being short-circuited by contacting an adjacent first conductive pattern 131 other than the first conductive pattern 131 to which the one of the vias 134 is electrically connected. For example, one of the vias 134 may be in contact (e.g., may overlap in the vertical direction) with only one of the first conductive patterns 131. As used herein, “an element A overlapping an element B in a direction X” (or similar language) means that there is at least one line that extends in the direction X and intersects both the elements A and B.

The second dielectric patterns 133 may include a dielectric material that is the same as or different from that included in the first dielectric patterns 132, for example, the dielectric material included in the second dielectric patterns 133 may have or exhibit a dielectric constant of (about) 2.5 to (about) 6.0 and a leakage current of (about) 3×10⁻⁷ A/cm² or less at 5 MV/cm. For example, the dielectric material included in the second dielectric patterns 133 may have a dielectric constant of (about) 2.5 to (about) 5.0, (about) 2.7 to (about) 5.0, or (about) 3.0 to (about) 5.0 and a leakage current of (about) 1×10⁻¹² A/cm² to (about) 3×10⁻⁷ A/cm² at 5 MV/cm. The second dielectric pattern 133 may include, for example, a silicon oxide.

The second layer L2 may be an interlayer dielectric layer and may include vias 134 (electrically) connected to the first conductive patterns 131, respectively. Each of the vias 134 may (electrically) connect one of the first conductive patterns 131 and one of the second conductive patterns 135 of the third layer L3. A width of the via 134 (in the first horizontal direction) may be equal to or wider than that of the first conductive pattern 131, and for example, the via 134 may be in contact with a side surface and an upper surface of the second dielectric pattern 133.

The third layer L3 may include the second conductive patterns 135, and the second conductive patterns 135 may be electrically connected to the first conductive patterns 131 through vias 134. The second conductive patterns 135 may include the same metal as or different metal from the metal included in the first conductive patterns 131. For example, the second conductive patterns 135 may include Cu, Ti, Ta, Al, W, Co, Mo, Ru, an alloy thereof, and/or a combination thereof, but is not limited thereto.

Hereinafter, some embodiments of a method of manufacturing the metal connection portion 130 shown in FIG. 2 will be described.

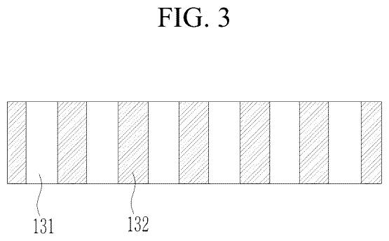

FIGS. 3 to 8 are cross-sectional views showing some embodiments of a method of manufacturing the metal connection portion 130 of FIG. 2.

Referring to FIG. 3, the first conductive patterns 131 and the first dielectric patterns 132 may be alternately arranged (in the first horizontal direction) to form the first layer L1.

To form the first layer L1, an interlayer dielectric layer may be first deposited and photoetched to remove a predetermined area. The predetermined area may be an area where (at least one of) the first conductive patterns 131 will be positioned, and may be, for example, linearly extending in one direction (e.g., in the second horizontal direction). Next, a metal or a metal alloy may be deposited on (in) the removed area to form a conductive layer (e.g., a metal layer), and the interlayer dielectric layer and the conductive layer may be planarized using, for example, chemical mechanical polishing (CMP). Accordingly, the first layer L1 having a cross section in which the first conductive patterns 131 and the first dielectric patterns 132 are alternately arranged may be formed.

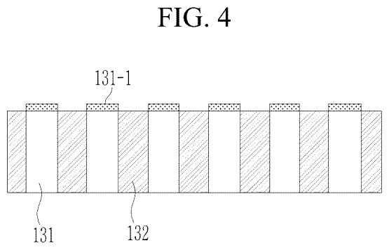

Referring to FIG. 4, a passivation layer 131-1 may be selectively formed on (at least one of) the first conductive patterns 131. For example, the passivation layer 131-1 may overlap with one of the first conductive patterns 131 in the vertical direction. Each of the passivation layers 131-1 may be on one of the first conductive patterns 131, respectively. The passivation layer 131-1 may be a blocking layer to shield the surfaces (e.g., upper surfaces) of the first conductive patterns 131 so that the metal catalyst for the second dielectric patterns 133 is selectively formed only on the first dielectric patterns 132 in the forming the second dielectric patterns 133, which will be described later and may provide an inactive area during the area-selective atomic layer deposition, which will be described later.

The passivation layer 131-1 may be, for example, a self-assembled monolayer (SAM). The self-assembled monolayer may include a mono-molecule with different surface properties, for example, including a hydrophilic functional group on one end and a hydrophobic portion on the other end. Accordingly, the hydrophilic functional group may be selectively self-assembled on the surfaces (e.g., the upper surfaces) of the first conductive patterns 131, and the hydrophobic portion may serve to block the adsorption of the metal catalyst in the forming the second dielectric patterns 133, which will be described later. For example, the self-assembled monolayer may be formed using a self-assembled mono-molecule selected from C3 to C30 hydrocarbon compounds including a thiol group, an amine group, and/or a carboxyl group, such as 1-dodecanethiol (DDT), 1-tetradecanethiol (TDT), and/or a combination thereof, but is not limited thereto.

The forming the self-assembled monolayer may include, for example, providing the self-assembled mono-molecule in a vapor state at a temperature of (about) 100 to 350° C. for (about) 1 to 20 minutes, and may further include an additional purge. The additional purge may use inert gas supplied at a predetermined flow rate, for example, nitrogen gas, argon gas, and/or a combination thereof may be supplied for (about) 30 to 300 seconds.

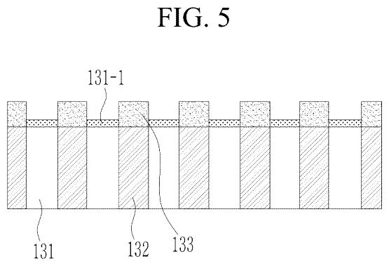

Referring to FIG. 5, the second dielectric patterns 133 may be selectively formed on the first dielectric patterns 132. Each of the second dielectric patterns 133 may be on one of the first dielectric patterns 132, respectively. The second dielectric patterns 133 may include, for example, an oxide film formed by an area-selective atomic layer deposition. The area-selective atomic layer deposition may selectively form a film or a layer with several to tens of nanometers thick in a specific area without a patterning process, for example, an oxide film may be selectively formed only in areas excluding the inactive area covered with the passivation layer 131-1. The area-selective atomic layer deposition may not require plasma, unlike plasma enhanced chemical vapor deposition (PECVD), so it may effectively reduce or prevent damage to the underlying film including the self-assembled monolayer described above (e.g., the passivation layer 131-1).

The area-selective atomic layer deposition may use a metal catalyst and a reaction precursor.

The metal catalyst may provide high selectivity to the surface of the passivation layer 131-1, which is the self-assembled monolayer described above, and accordingly, the metal catalyst may induce that the reaction precursor is selectively adsorbed on the surface of the first dielectric patterns 132 on which the passivation layer 131-1 is not formed. The metal catalyst may be, for example, an aluminum catalyst, and/or may include, for example, trimethylaluminum (TMA), triethylaluminum (TEA), dimethylaluminum iso-propoxide (DMAI), and/or a combination thereof, but is not limited thereto.

The reaction precursor may react with the metal catalyst (e.g., by a condensation reaction) to form an oxide film. The reaction precursor may be, for example, a silanol precursor, such as tris(t-pentoxy)silanol (TTPS), bis(t-pentoxy)(t-butoxy)silanol (BTPTBS), and/or a combination thereof, but is not limited thereto.

In this way, the oxide film formed by the area-selective atomic layer deposition using the metal catalyst and the reaction precursor may have an advantage capable of being selectively formed in a specific area without a patterning process. On the other hand, the film properties and electrical properties of the oxide film formed by the area-selective atomic layer deposition using the metal catalyst and the reaction precursor may be strongly temperature-dependent, so in order to obtain desired (good) film properties and electrical properties, the area-selective atomic layer deposition may be performed at a relatively high temperature of higher than 350° C. and/or may need a post-deposition annealing at a temperature of (about) 400° C. or higher.

According to embodiments of the inventive concept, the detailed process of the area-selective atomic layer deposition may be effectively controlled to obtain the second dielectric patterns 133 with desired (good) film properties and electrical properties without a high-temperature deposition process or an additional post-deposition annealing. For example, the area-selective atomic layer deposition may be performed at a temperature of (about) 350° C. or less (lower). For example, the area-selective atomic layer deposition may be performed at a temperature of (about) 300° C. or less (lower), (about) 250° C. or less (lower), (about) 100° C. to 350° C., (about) 100° C. to 300° C., (about) 100° C. to 250° C., or (about) 150° C. to 250° C., and the temperature may be maintained throughout the area-selective atomic layer deposition process.

Specifically, the area-selective atomic layer deposition may include pulsing (pulse feeding or pulse supply of) the metal catalyst on the surface of the first dielectric patterns 132, performing a primary purge, sub-pulsing (sub-pulse feeding or sub-pulse supply of) the reaction precursor for the second dielectric patterns 133 once or multiple times, and performing a secondary purge after each of the sub-pulsing.

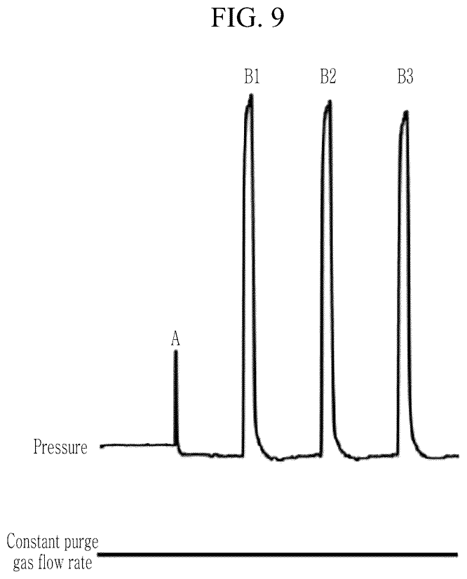

As an example embodiment, referring to FIG. 9, the area-selective atomic layer deposition may be performed by a continuous flow process. The continuous flow process may provide a purge gas with a constant flow rate and a constant pressure.

For example, first, the metal catalyst (e.g., aluminum catalyst) may be pulsed (A) (may be supplied by the pulse feeding) while a purge gas is supplied with a first flow rate and a first pressure.

Next, the primary purge may be performed while the purge gas is supplied with the first flow rate and the first pressure (maintain the first flow rate and the first pressure). The purge gas may be, for example, an inert gas such as nitrogen gas, argon gas, and/or a combination thereof.

Next, the reaction precursor (e.g., silanol) may be sub-pulsed once (B1) or several times (B1, B2, and B3) (may be supplied by the sub-pulse feeding once or several times). The reaction precursor may be prepared by heating to (about) 50° C. or higher, within the above range (e.g., lower than 350° C.). For example, the reaction precursor may be prepared by heating to (about) 50 to 120° C. or (about) 70 to 100° C. The sub-pulse feeding of the reaction precursor may be performed 1 to 20 times, but is not limited thereto. The sub-pulse feeding of the reaction precursor may be performed while the purge gas is supplied with the first flow rate and the first pressure (maintain the first flow rate and the first pressure).

After each sub-pulse feeding, the secondary purge may be performed while the purge gas is supplied with the first flow rate and the first pressure (maintain the first flow rate and the first pressure).

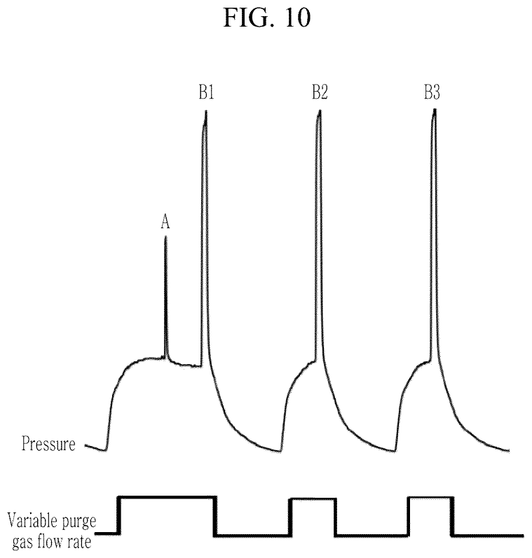

As another example embodiment, referring to FIG. 10, the area-selective atomic layer deposition may be performed by a pump-purge process. The pump-purge process may include supplying the purge gas, reducing the purge gas supply for a predetermined period of time, and increasing the purge gas supply again. For example, the purge gas supply may be reduced to 0 standard cubic centimeters per minute (sccm) for the predetermined period of time (e.g., gradually reducing it until the lowest pressure and/or the lowest flow rate is reached) and increased again to a certain flow rate and/or a certain pressure, which may be, for example, the initial flow rate and/or the initial pressure, respectively, before the reduction of the purge gas supply. The purge gas may be provided with a variable flow rate and a variable pressure.

For example, first, the metal catalyst (e.g., aluminum catalyst) may be pulsed (A) (may be supplied by the pulse feeding). The pressure of the purge gas supply may vary before and/or after pulsing the metal catalyst.

Next, the primary purge may be performed while the purge gas is supplied. The purge gas may be an inert gas such as nitrogen gas, argon gas, and/or a combination thereof. The primary purge may supply the purge gas for (about) 5 to 30 seconds with a pressure of (about) 1 Torr or less. For example, the pressure of the purge gas supply during the primary purge may be (about) 0.01 Torr to 1 Torr or (about) 0.1 Torr to 0.8 Torr.

Next, the reaction precursor (e.g., silanol) may be sub-pulsed once (B1) or multiple times (B1, B2, and B3) (may be supplied by the sub-pulse feeding once or multiple times). The reaction precursor may be prepared by heating to (about) 50° C. or higher, within the above range (e.g., lower than 350° C.). For example, the reaction precursor may be prepared by heating to (about) 50 to 120° C. or (about) 70 to 100° C. The sub-pulse feeding of the reaction precursor may be performed 1 to 20 times, but is not limited thereto.

After each sub-pulse, pumping and a secondary purge may be performed. For example, the pumping may be performed between each sub-pulse and the secondary purge.

The pumping may cease supplying the purge gas (flow rate: 0 sccm) or supply the purge gas with a reduced flow rate than the flow rate of the purge gas in the primary purge until the purge gas pressure reaches a low pressure of less than (about) 0.1 Torr.

In some embodiments, the secondary purge may be performed while supplying the purge gas with the same flow rate and the same pressure as the primary purge, and may be performed for (about) 2 to 30 seconds.

The above-described pulsing the metal catalyst, the primary purge, and the sub-pulsing the reaction precursor for the second dielectric patterns 133 (including the secondary purge) may form one cycle, and this cycle may be repeated one or more times, for example, until the second dielectric patterns 133 with a desired thickness are formed. For example, the above-described cycle may be repeated for 2 to 10 cycles, and a tertiary purge may be further included before of the repeating (before each cycle). The tertiary purge may, for example, supply a purge gas for (about) 5 to 30 seconds with a pressure of (about) 1 Torr or less, but is not limited thereto.

In this way, the area-selective atomic layer deposition may add the performing the purges between the pulsing of the metal catalyst and the sub-pulsing of the reaction precursor and/or between the sub-pulses of the reaction precursor in a continuous flow process or a pump-purge process, and in the performing the purges, by effectively controlling various factors such as flow rate, pressure, and/or time, the quality of the oxide film formed therefrom may be effectively controlled. It may be expected that this is due to the fact that trapped water (e.g., by-products from a condensation reaction of the metal catalyst and the reaction precursor) and organic reaction by-products inevitably generated during the process are effectively reduced or removed by the above process (the performing the purges). Therefore, the electrical characteristics of the second dielectric patterns 133 may be improved without a high temperature process or an additional post-deposition annealing.

For example, the second dielectric patterns 133 may include a silicon oxide formed according to the above-described process using silanol precursor as a reaction precursor, so that the obtained silicon oxide may satisfy a dielectric constant of (about) 2.5 to (about) 6.0, a leakage current of (about) 3×10⁻⁷ A/cm² or less at 5 MV/cm, and a breakdown field of (about) 8 to 11 MV/cm without a high temperature process of (about) higher than 350° C. or an additional post-deposition annealing.

Subsequently, the passivation layer 131-1 may be removed.

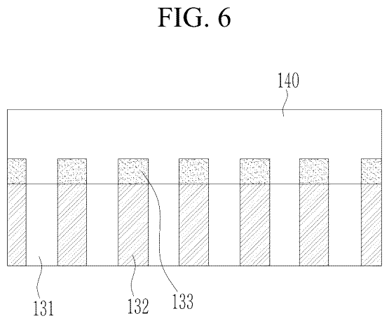

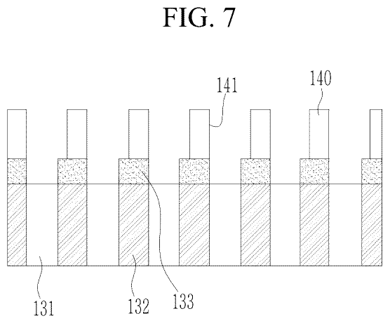

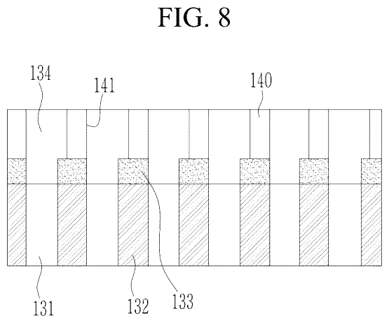

Referring to FIG. 6, an interlayer dielectric layer 140 may be formed on the first conductive patterns 131 and the second dielectric patterns 133. Next, referring to FIG. 7, the interlayer dielectric layer 140 may be photoetched to form via holes 141 and expose the first conductive patterns 131. Next, referring to FIG. 8, the via holes 141 may be (at least partially) filled with a conductor (e.g., conductive material) to form the vias 134. Next, referring to FIG. 2, the second conductive patterns 135 may be formed on the interlayer dielectric layer 140 and the vias 134.

Hereinafter, the embodiments are illustrated in more detail with reference to examples. However, these examples are not restrictive, and the scope of claims is not limited thereto.

### EXAMPLES I

### Example 1

Tris(t-pentoxy)silanol (TTPS) precursor is heated to 95° C., and trimethylaluminum (TMA) catalyst is unheated at room temperature of (about) 24° C. Atomic layer deposition (ALD) (the area-selective atomic layer deposition) of silicon oxide film is carried out at 200° C. in a 200 mm-diameter cross-flow reactor using the continuous flow process, wherein N₂ purge gas is supplied with 0.17 Torr pressure and 20 sccm flow rate. For each cycle of the ALD, TMA catalyst is pulsed for 0.015 second, purged for 15 seconds, followed by 10 sub-pulses of TTPS precursor delivered by vapor draw for 2 seconds per sub-pulse followed by a 5 second purge after each sub-pulse, and finally purged for another 10 seconds before the next cycle. This process is repeated for a total of 6 cycles until (about) 250 Å of silicon oxide film is deposited on a 45 mm×45 mm silicon substrate with native oxide.

### Example 2

TTPS precursor is heated to 95° C. and TMA catalyst is unheated at room temperature of (about) 24° C. ALD of silicon oxide film is carried out at 175° C. in a 200 mm-diameter cross flow reactor using the continuous flow process, wherein N₂ purge gas is supplied with 0.17 Torr pressure and 20 sccm flow rate. For each cycle of ALD, TMA catalyst is pulsed for 0.015 second, purged for 15 seconds, followed by 10 sub-pulses of TTPS precursor delivered by vapor draw for 2 seconds per sub-pulse followed by a 10 second purge after each sub-pulse, and finally purged for another 10 seconds before the next cycle. This process is repeated for a total of 4 cycles until (about) 300 Å of silicon oxide film is deposited on a 45 mm×45 mm silicon substrate with native oxide.

### Example 3

TTPS precursor is heated to 90° C. and TMA catalyst is unheated at room temperature of (about) 24° C. ALD of silicon oxide film is carried out at 175° C. in a 200 mm-diameter cross flow reactor using the continuous flow process, wherein N₂ purge gas is supplied with 0.11 Torr pressure and 10 sccm flow rate. For each cycle of ALD, TMA catalyst is pulsed for 0.015 second, purged for 15 seconds, followed by 15 sub-pulses of TTPS precursor delivered by vapor draw for 2 seconds per sub-pulse followed by a 10 second purge after each sub-pulse, and finally purged for another 10 seconds before the next cycle. This process is repeated for a total of 4 cycles until (about) 260 Å of silicon oxide film is deposited on a 45 mm×45 mm silicon substrate with native oxide.

### Example 4

TTPS precursor is heated to 95° C. and TMA catalyst is unheated at room temperature of (about) 24° C. ALD of silicon oxide film is carried out at 150° C. in a 200 mm-diameter cross flow reactor using the continuous flow process, wherein N₂ purge gas is supplied with 0.17 Torr pressure and 20 sccm flow rate. For each cycle of ALD, TMA catalyst is pulsed for 0.015 second, purged for 15 seconds, followed by 10 sub-pulses of TTPS precursor delivered by vapor draw for 2 seconds per sub-pulse followed by a 15 second purge after each sub-pulse, and finally purged for another 10 seconds before the next cycle. This process is repeated for a total of 3 cycles until (about) 325 Å of silicon oxide film is deposited on a 45 mm×45 mm silicon substrate with native oxide.

### Example 5

TTPS precursor is heated to 90° C. and TMA catalyst is unheated at room temperature of (about) 24° C. ALD of silicon oxide film is carried out at 150° C. in a 200 mm-diameter cross flow reactor using the continuous flow process, wherein N₂ purge gas is supplied with 0.11 Torr pressure and 10 sccm flow rate. For each cycle of ALD, TMA catalyst is pulsed for 0.015 second, purged for 15 seconds, followed by 15 sub-pulses of TTPS precursor delivered by vapor draw for 2 seconds per sub-pulse followed by a 15 second purge after each sub-pulse, and finally purged for another 10 seconds before the next cycle. This process is repeated for a total of 4 cycles until (about) 265 Å of silicon oxide film is deposited on a 45 mm×45 mm silicon substrate with native oxide.

### Example 6

TTPS precursor is heated to 88° C. and TMA catalyst is unheated at room temperature of (about) 24° C. ALD of silicon oxide film is carried out at 150° C. in a 200 mm-diameter cross flow reactor using the pump-purge process. For each cycle of ALD, TMA catalyst is pulsed for 0.015 second and purged for 15 seconds while N₂ purge gas is supplied with 0.11 Torr pressure and 10 sccm flow rate, followed by 8 sub-pulses of TTPS precursor as follows: each sub-pulse of TTPS precursor is delivered by vapor draw for 2 seconds with 10 sccm N₂ purge gas flow, pumped for 30 seconds with 0 sccm of N₂ purge gas flow down to base pressure of (about) 0.034 Torr, and purged for 15 seconds with 10 sccm N₂ purge gas flow, and finally purged for another 10 seconds before the next cycle. This process is repeated for a total of 4 cycles until (about) 230 Å of silicon oxide film is deposited on a 45 mm×45 mm silicon substrate with native oxide.

### Example 7

Mixed-ligand precursor, bis(tert-pentoxy)(tert-butoxy)silanol (BTPTBS) precursor, is heated to 80° C. and TMA catalyst is unheated at room temperature of (about) 24° C. ALD of silicon oxide film is carried out at 150° C. using the pump-purge process. For each cycle of ALD, TMA catalyst is pulsed for 0.015 second and purged for 15 seconds while N₂ purge gas is supplied with 0.11 Torr pressure and 10 sccm flow rate, followed by 10 sub-pulses of BTPTBS precursor as follows: each sub-pulse of BTPTBS precursor is delivered by vapor draw for 2 seconds with 10 sccm N₂ purge gas flow, pumped for 30 seconds with 0 sccm of N₂ purge gas flow down to base pressure of (about) 0.034 Torr, purged for 15 seconds with 10 sccm N₂ purge gas flow, and finally purged for another 10 seconds before the next cycle. This process is repeated for a total of 4 cycles until (about) 218 Å of silicon oxide film is deposited on a 45 mm×45 mm silicon substrate with native oxide.

### Evaluation I

The silicon oxide films according to Examples are analyzed by Fourier Transform Infrared Spectroscopy (FTIR).

FTIR is analyzed using a Nicolet IS50 FT-IR system (Thermo Fisher Scientific Inc.).

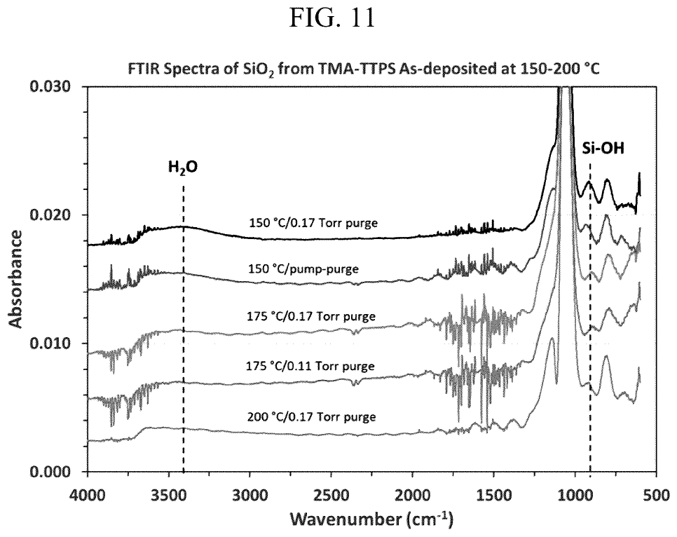

The results are as shown in FIG. 11.

FIG. 11 is a FTIR analysis graph of the silicon oxide films obtained in Examples.

Referring to FIG. 11, although Example 6 (150° C./pump-purge) and Example 4 (150° C., 0.17 Torr purge) are performed at the same temperature (150° C.), it is confirmed that the silicon oxide film according to Example 6 using the pump-purge process has reduced H₂O (3400 cm⁻¹) and Si—OH (900 cm⁻¹) compared to the silicon oxide film according to Example 4.

Additionally, although Example 2 (175° C./0.17 Torr purge) and Example 3 (175° C./0.11 Torr purge) are performed at the same temperature (175° C.), it is confirmed that the silicon oxide film according to Example 3 performed at a lower purge pressure (0.11 Torr) has reduced H₂O (3400 cm⁻¹) and Si—OH (900 cm⁻¹) compared to the silicon oxide film according to Example 2.

Additionally, although Example 1 (200° C./0.17 Torr purge), Example 2 (175° C./0.17 Torr purge) and Example 4 (150° C./0.17 Torr purge) are performed under the same pressure (0.17 Torr), it is confirmed that the silicon oxide film according to Example 1 performed at a higher temperature (200° C.) has reduced H₂O (3400 cm⁻¹) and Si—OH (900 cm⁻¹) compared to the silicon oxide films according to Examples 2 and 4.

### Evaluation II

The MISCAP (metal-insulator-semiconductor capacitor) devices including the silicon oxide films according to Examples are manufactured and its electrical properties are evaluated.

The MISCAP device has a stacked structure of p-type silicon substrate (45 mm×45 mm)/native oxide (with thickness of 12˜15 Å)/SiO₂ layer (formed by ALD)/TiN electrode.

Here, the SiO₂ layers are silicon oxide films according to Examples 1 to 7, and the TiN electrode is formed to have a thickness of (about) 200 Å by sputtering at (about) 250° C. and patterned through a general photoetching process.

The electric characteristics are evaluated using Keysight B1500A Semiconductor Device Parameter Analyzer equipped with HRSMU (high resolution source/monitor unit) module for evaluating leakage current and MFCMU (multi-frequency capacitance measurement unit) module for evaluating capacitance.

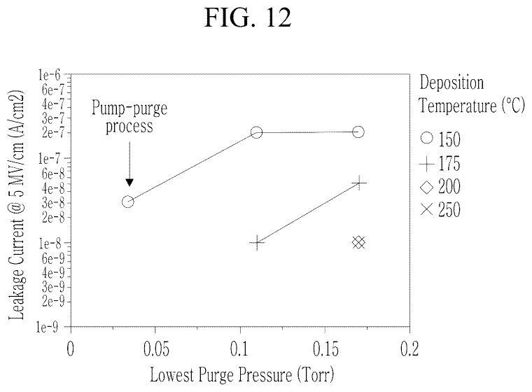

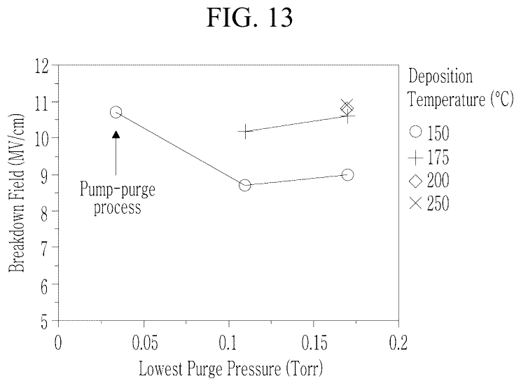

The results are as shown in Table 1 and FIGS. 12 and 13.

FIG. 12 is a graph showing the change in leakage current at 5 MV/cm according to deposition temperature and purge gas pressure during the formation of a silicon oxide film, and FIG. 13 is a graph showing the change in breakdown field according to deposition temperature and purge gas pressure during the formation of a silicon oxide film.

TABLE 1

| | Dielectric | Leakage Current | Breakdown Field |
|---|---|---|---|
| | Constant | (A/cm², @ 5 MV/cm) | (MV/cm) |
| Example 1 | 4.3 | 1.0 × 10⁻⁸ | 10.8 |
| Example 2 | 4.6 | 5.0 × 10⁻⁸ | 10.6 |
| Example 3 | — | 1.0 × 10⁻⁸ | 10.2 |
| Example 4 | 4.9 | 2.0 × 10⁻⁷ | 9.0 |
| Example 5 | — | 2.0 × 10⁻⁷ | 8.7 |
| Example 6 | 4.6 | 3.0 × 10⁻⁸ | 10.7 |
| Example 7 | 4.4 | 3.0 × 10⁻⁸ | 10.3 |

Referring to Table 1 and FIGS. 12 and 13, it is confirmed that the devices including the silicon oxide films according to Examples have desired (good) electrical characteristics using a continuous flow process at 200 to 250° C. with 0.17 Torr pressure (e.g., Example 1), a continuous flow process at 175° C. with 0.11 Torr pressure (e.g., Example 3), and a pump-purge process at 150° C. (e.g., Example 6). Examples II

### Example 8

A 25 mm×25 mm silicon substrate with a copper film on an upper surface thereof and a 25 mm×25 mm silicon substrate with native oxide are each etched in an aqueous solution containing 2 wt % of citric acid for 2.5 to 3 minutes, then rinsed with distilled water 3 times for 1 minute each. The substrates are blown dry with nitrogen gas, immediately loaded to the center (the central area) of a 200 mm-diameter cross flow reactor heated to 80° C., pumped down to base pressure (e.g., 0.034 Torr), then heated up gradually to 150° C. with 10 sccm of nitrogen purge gas flow. 1-dodecanethiol (DDT) liquid in a stainless ampule is heated to 100° C., delivered by vapor draw into the 200 mm-diameter cross flow reactor at 150° C. for 5 minutes continuously without carrier or purge gas to selectively form a SAM passivation layer on the copper film, purged with 20 sccm of nitrogen purge gas flow for 90 seconds, then deposited in-situ at the same temperature of 150° C. without vacuum break for 2 cycles of ALD of silicon oxide using the process described in Example 6. The substrates are cooled down to 80° C. before exposing (opening) to air for unloading.

### Example 9

A 25 mm×25 mm silicon substrate with a copper film on an upper surface thereof and a 25 mm×25 mm silicon substrate with native oxide are each etched in an aqueous solution containing 2 wt % of citric acid for 2.5 to 3 minutes, then rinsed with distilled water 3 times for 1 minute each. The substrates are blown dry with nitrogen gas, immediately loaded to the center (the central area) of a 200 mm-diameter cross flow reactor heated to 80° C., pumped down to base pressure (e.g., 0.034 Torr), then heated up gradually to 175° C. with 20 sccm of nitrogen purge gas flow. 1-tetradecanethiol (TDT) in a stainless ampule is heated to 110° C., vapor draw delivered into the 200 mm-diameter cross flow reactor at 175° C. for 5 minutes continuously without carrier or purge gas to selectively form a SAM passivation layer on the copper film, purged with 20 sccm of nitrogen purge gas flow for 60 seconds, then deposited in-situ at the same temperature of 175° C. without vacuum break for 2 cycles of ALD of silicon oxide using the process described in Example 2. The substrates are cooled down to 80° C. before exposing (opening) to air for unloading.

### Example 10

A 25 mm×25 mm silicon substrate with a copper film on an upper surface thereof and a 25 mm×25 mm silicon substrate with native oxide are each etched in an aqueous solution containing 2 wt % of citric acid for 2.5 to 3 minutes, then rinsed with distilled water 3 times for 1 minute each. The substrates are blown dry with nitrogen gas, immediately loaded to the center (the central area) of a 200 mm-diameter cross flow reactor heated to 80° C., pumped down to base pressure (e.g., 0.034 Torr), then heated up gradually to 200° C. with 20 sccm of nitrogen purge gas flow. 1-dodecanethiol (DDT) in a stainless ampule is heated to 100° C., vapor draw delivered into the 200 mm-diameter cross flow reactor at 200° C. continuously for 2 minutes without carrier or purge gas to selectively form a SAM passivation layer on the copper film, purged with 20 sccm of nitrogen purge gas flow for 30 seconds, then deposited in-situ at the same temperature of 200° C. without vacuum break for 2 cycles of ALD of silicon oxide using the process described in Example 1. The substrates are cooled down to 80° C. before exposing (opening) to air for unloading.

### Example 11

A 25 mm×25 mm silicon substrate with a copper film on an upper surface thereof and a 25 mm×25 mm silicon substrate with native oxide are each etched in an aqueous solution containing 2 wt % of citric acid for 2.5 to 3 minutes, then rinsed with distilled water 3 times for 1 minute each. The substrates are blown dry with nitrogen gas, immediately loaded to the center (the central area) of a 200 mm-diameter cross flow reactor heated to 80° C., pumped down to base pressure (e.g., 0.034 Torr), then heated up gradually to 250° C. with 20 sccm of nitrogen purge gas flow. 1-dodecanethiol (DDT) in a stainless ampule is heated to 110° C., vapor draw delivered into the 200 mm-diameter cross flow reactor at 250° C. continuously for 2 minutes without carrier or purge gas to selectively form a SAM passivation layer on the copper film, purged with 20 sccm of nitrogen purge gas flow and 0.17 Torr of purge gas pressure for 15 seconds, followed by 2 cycles of in-situ ALD deposition of silicon oxide at the same pressure of 0.17 Torr and same temperature of 250° C. without vacuum break using a single-pulse continuous flow process as follows: TMA pulse 0.015 second, purge 15 seconds, 15 second pulse of TTPS, and finally 15 second purge at the same pressure for each cycle. The substrates are cooled down to 80° C. before exposing (opening) to air for unloading.

### Evaluation III

Selectivity according to the area-selective atomic layer deposition (also referred to as ALD herein) of silicon oxide films according to Examples are evaluated.

Selectivity is evaluated by measuring the thicknesses of the silicon oxide film on the copper non-grown surface and the silicon oxide film on the native oxide surface.

The thickness of the silicon oxide film on the copper non-grown surface is calculated from Si(at %) values measured using XPS analysis (Thermo Scientific K-Alpha+ XPS Spectrometer) based on samples with known SiO₂ thickness.

The thickness of the silicon oxide film on the native oxide surface is measured using a Woollam Alpha-SE Ellipsometer. Selectivity is calculated according to Equation below.

$$selectivity ( \% ) = ( ( thickness {T}_{1} on native oxide growth surface - thickness {T}_{2} on Cu non - growth surface ) \times 100 ) / thickness {T}_{1} on native oxide growth surface \qquad [ Equation ]$$

The results are as shown in Table 2.

TABLE 2

| | Deposition | | | Selectivity |
|---|---|---|---|---|
| | Temperature(° C.) | T₁ (Å) | T₂ (Å) | (%) |
| Example 8 | 150 | 195 | 2.4 | 98.8 |
| Example 9 | 175 | 140 | 9.5 | 93.2 |
| Example 10 | 200 | 108 | 11.6 | 89.3 |
| Example 11 | 250 | 32.5 | 1.8 | 94.5 |

* T₁: thickness on native oxide growth surface
* T₂: thickness on Cu non-growth surface

Referring to Table 2, it is confirmed that the selectivity of the silicon oxide films according to Examples is determined depending on the deposition temperature and the thickness of the silicon oxide film on the native oxide growth surface.

While this disclosure has been described in connection with what is presently considered to be practical example embodiments, it is to be understood that the invention is not limited to the disclosed embodiments. On the contrary, it is intended to cover various modifications and equivalent arrangements included within the scope of the appended claims.

What is claimed is:

1. A method of manufacturing a semiconductor device comprising:
forming a first layer in which first conductive patterns and first dielectric patterns are alternately arranged;
forming passivation layers on the first conductive patterns, respectively; and
forming second dielectric patterns on the first dielectric patterns, respectively, by an area-selective atomic layer deposition at a first temperature, wherein the first temperature is 350° C. or less,
wherein the area-selective atomic layer deposition includes:
pulsing a metal catalyst;
performing a primary purge by a purge gas;
sub-pulsing a reaction precursor at least once; and
performing a secondary purge by the purge gas after each of the sub-pulsing.

2. The method of claim 1, wherein the purge gas is continuously supplied with a constant flow rate and a constant pressure during the area-selective atomic layer deposition.

3. The method of claim 2, wherein the constant pressure of the purge gas is 1 Torr or less.

4. The method of claim 1, wherein the area-selective atomic layer deposition further includes pumping the purge gas between the sub-pulsing the reaction precursor and the secondary purge.

5. The method of claim 4, wherein the purge gas of the performing the primary purge has a first flow rate and a first pressure,
wherein the purge gas of the pumping the purge gas has a second flow rate and a second pressure, and
wherein the purge gas of the performing the second purge has a third flow rate and a third pressure.

6. The method of claim 5, wherein, the first flow rate is greater than the second flow rate,
wherein the third flow rate is greater than the second flow rate,
wherein the first pressure is greater than the second pressure, and
wherein the third pressure is greater than the second pressure.

7. The method of claim 6, wherein the second flow rate is zero (0) standard cubic centimeters per minute (sccm), and
wherein the second pressure is 0.1 Torr or less.

8. The method of claim 1, wherein the first temperature is 150° C. to 350° C.

9. The method of claim 1, wherein the metal catalyst includes trimethylaluminum, triethylaluminum, dimethylaluminum iso-propoxide, and/or a combination thereof.

10. The method of claim 1, wherein the reaction precursor is a silanol precursor, and
wherein the second dielectric patterns include silicon oxide.

11. The method of claim 10, wherein the silanol precursor includes tris(t-pentoxy)silanol, bis(t-pentoxy)(t-butoxy)silanol, and/or a combination thereof.

12. The method of claim 1, wherein
the forming the passivation layers includes supplying a self-assembled molecule that includes a thiol group material, an amine group material, and/or a carboxylic group material.

13. The method of claim 12, wherein the supplying the self-assembled molecule is performed at a second temperature of 100° C. to 350° C.

14. The method of claim 13, wherein the forming the passivation layers further includes performing additional purge after the supplying the self-assembled molecule.

15. The method of claim 1, further comprising:
repeating the area-selective atomic layer deposition until the second dielectric patterns reach to a desired thickness, and
performing a tertiary purge before the repeating the area-selective atomic layer deposition.

16. The method of claim 1, wherein the second dielectric patterns include a dielectric material that has a dielectric constant of 2.5 to 6.0.

17. The method of claim 1, wherein the second dielectric patterns include a dielectric material that has a leakage current of 3×10⁻⁷ A/cm² or less at 5 MV/cm.

18. The method of claim 1, wherein the first dielectric patterns and the second dielectric patterns each include silicon oxide.

19. The method of claim 1, further comprising:
forming vias electrically connected to the first conductive patterns; and
forming second conductive patterns electrically connected to the first conductive patterns through the vias.

20. A semiconductor device comprising:
a first layer including first conductive patterns and first dielectric patterns;
second dielectric patterns on the first dielectric patterns, wherein the second dielectric patterns have same planar shapes as the first dielectric patterns, respectively, and include a dielectric material that has a dielectric constant of 2.5 to 6.0 and a leakage current of 3×10⁻⁷ A/cm² or less at 5 MV/cm;
a second layer electrically connected to the first conductive patterns, wherein the second layer includes vias that are in contact with the second dielectric patterns; and
a third layer including second conductive patterns that are electrically connected to the first conductive patterns through the vias,
wherein the semiconductor device is manufactured by a method comprising:
forming the first layer in which the first conductive patterns and the first dielectric patterns are alternately arranged;
forming passivation layers on the first conductive patterns, respectively; and
forming the second dielectric patterns on the first dielectric patterns, respectively, by an area-selective atomic layer deposition at a first temperature, wherein the first temperature is 350° C. or less, and
wherein the area-selective atomic layer deposition includes:
pulsing a metal catalyst;
performing a primary purge by a purge gas;
sub-pulsing a reaction precursor at least once; and
performing a secondary purge by the purge gas after each of the sub-pulsing.
